(19) United States
(12) Patent Application Publication
(10) Pub. No.: US 2013/0168853 A1
(43) Pub. Date: Jul. 4, 2013

(54) PACKAGE SUBSTRATE AND METHOD OF FABRICATING THE SAME

(71) Applicant: Samsung Electro-Mechanics Co., Ltd., Suwon (KR)

(72) Inventors: Hyo Bin PARK, Daejeon (KR); Jeong Suk Lee, Gunpo (KR); Ji Hyun Eom, Chungcheongnam (KR); Nam Gil Lee, Chungcheongnam (KR)

(73) Assignee: SAMSUNG ELECTRO-MECHANICS CO., LTD., Suwon (KR)

(21) Appl. No.: 13/729,560

(22) Filed: Dec. 28, 2012

(30) Foreign Application Priority Data
Dec. 30, 2011 (KR) 10-2011-0146878

(51) Int. Cl. H01L 23/498; H01L 21/768

(52) U.S. Cl. CPC H01L 23/49811; H01L 21/76895
USPC 257/737; 438/612

(57) ABSTRACT

Disclosed herein are a package substrate and a method of fabricating the same. The method of fabricating the package substrate includes preparing a base substrate, forming a metal material layer surrounding an entire surface of the base substrate, forming sacrificial patterns on partial regions of the base substrate on which the metal material layer is formed, forming pads contacting lateral surfaces of the sacrificial patterns, forming a gold plating layer on upper surfaces of the pads, and removing the sacrificial patterns and removing portions of the metal material layer to form a conductive layer that remains on partial regions so as to contact lower surfaces of the pads.

### CROSS REFERENCE(S) TO RELATED APPLICATIONS

This application claims the benefit under 35 U.S.C. Section 119 of Korean Patent Application Serial No. 10-2011-0146878, entitled “Package Substrate and Method of Fabricating the Same” filed on Dec. 30, 2011, which is hereby incorporated by reference in its entirety into this application.

### BACKGROUND OF THE INVENTION

1. Technical Field

The present invention relates to a package substrate and a method of fabricating the same, and more particularly, to a package substrate and a method of fabricating the same, by which pitches between pads are miniaturized to achieve high-density packaging.

2. Description of the Related Art

Recently, as electronic products have been miniaturized, lightweight, and multifunctional, a system in package (SIP) technology has been commonly used.

According to the SIP technology, a plurality of semiconductor chips (semiconductor dies) are horizontally or vertically mounted on a single package substrate, and the semiconductor chips are adhered to each other via solder bumps by using a flip chip method.

In general, a package substrate includes a base substrate and pads formed on the base substrate, and may be electrically connected to semiconductor chips through the pads.

A gold plating layer formed of an electrolytic gold plating material or an electroless gold plating material is formed on the above-described pads in order to reduce contact resistance. The gold plating layer is formed to surround exposed surfaces of the pads. In this regard, an electrical short may occur during manufacturing processes, and intervals between the pads connected to the semiconductor chip may be narrowed.

Accordingly, in order to overcome these problems, as disclosed in Korean Patent Laid-Open Publication No. 2008-0100111, pads are embedded in a base substrate.

However, when the pad is embedded in the base substrate, separate raw materials, for example, a double-sided copper foil adhesive plate or a base copper layer attached to carriers, for embedding the pad in the base substrate are required.

In addition, a separate process, for example, a process for stacking laminates by applying heat and pressure to the laminates is required to embed pre-formed patterns in the base substrate, and thus, manufacturing cost and time are increased.

### RELATED ART DOCUMENT

### Patent Document

(Patent Document 1) Korean Patent Laid-Open Publication No. 2008-0100111 (laid-open published on Nov. 14, 2008)

### SUMMARY OF THE INVENTION

An object of the present invention is to provide a package substrate and a method of fabricating the same, by which manufacturing cost and time are reduced while still ensuring intervals between pads.

According to an exemplary embodiment of the present invention, there is provided a method of fabricating a package substrate, including: preparing a base substrate; forming a metal material layer surrounding an entire surface of the base substrate; forming sacrificial patterns on partial regions of the base substrate on which the metal material layer is formed; forming pads contacting lateral surfaces of the sacrificial patterns; forming a gold plating layer on upper surfaces of the pads; and removing the sacrificial patterns and removing portions of the metal material layer to form a conductive layer that remains on partial regions so as to contact lower surfaces of the pads.

The pads may each be formed to have a smaller height than that of each of the sacrificial patterns.

The gold plating layer may be formed to have a smaller height than that of each of the sacrificial patterns.

The method may further include forming an insulating layer on the base substrate, except for the partial regions.

According to another exemplary embodiment of the present invention, there is provided a package substrate, including: a base substrate; a conductive layer formed on partial regions of the base substrate; pads formed on the conductive layer; and a gold plating layer that is formed to contact upper surfaces of the pads.

The pads may be electrically connected to a semiconductor chip via bumps.

The package substrate may further include an insulating layer formed on the base substrate, except for the partial regions.

### BRIEF DESCRIPTION OF THE DRAWINGS

FIG. 1A is a cross-sectional view of a package substrate according to an embodiment of the present invention;

FIG. 1B is a cross-sectional view of the package substrate taken along a line I-I′ of FIG. 1A, according to an embodiment of the present invention; and

FIGS. 2 to 7 are cross-sectional views for describing a method of fabricating a package substrate, according to an embodiment of the present invention.

### DESCRIPTION OF THE PREFERRED EMBODIMENTS

Hereinafter, exemplary embodiments of the present invention will be described in detail with reference to the accompanying drawings. However, this is only by way of example and therefore, the present invention is not limited thereto.

When technical configurations known in the related art are considered to make the contents obscure in the present invention, the detailed description thereof will be omitted. Further, the following terminologies are defined in consideration of the functions in the present invention and may be construed in different ways by the intention of users and operators. Therefore, the definitions thereof should be construed based on the contents throughout the specification.

As a result, the spirit of the present invention is determined by the claims and the following exemplary embodiments may be provided to efficiently describe the spirit of the present invention to those skilled in the art.

Hereinafter, a package substrate according to exemplary embodiments of the invention will be described with reference to the accompanying drawings.

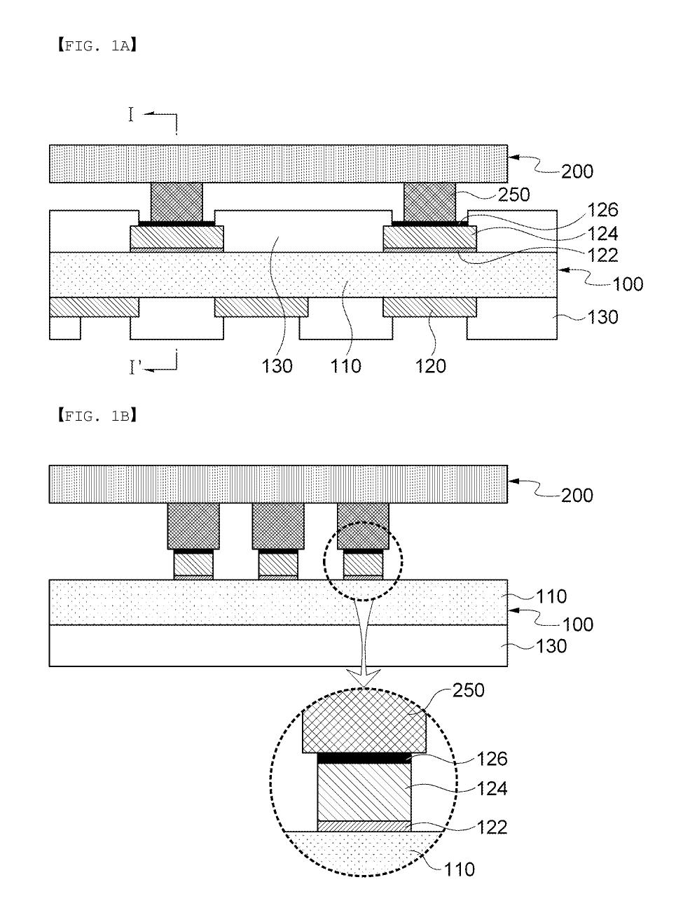

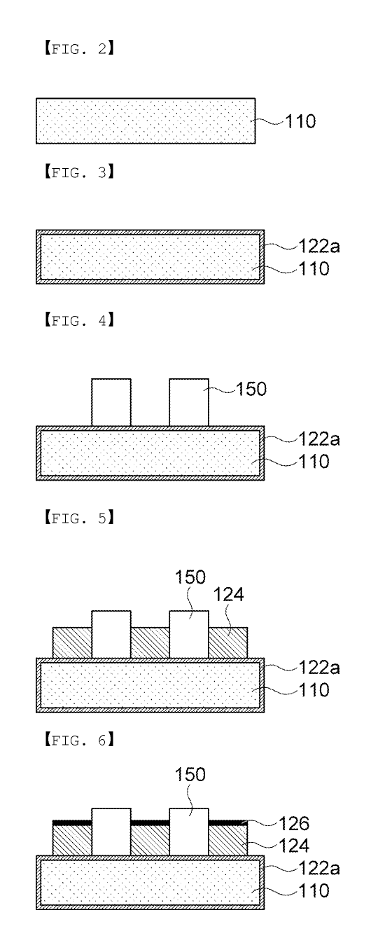

FIG. 1A is a cross-sectional view of a package substrate 100 according to an embodiment of the present invention. FIG. 1B is a cross-sectional view of the package substrate 100 taken along a line I-I′ of FIG. 1A, according to an embodiment of the present invention.

As shown in FIGS. 1A and 1B, the package substrate 100 according to an embodiment of the present embodiment includes a base substrate 110, a conductive layer 122, pads 124, and a gold plating layer 126.

The base substrate 110 may function as a support for forming patterns including the conductive layer 122, the pads 124, and the gold plating layer 126, and may be formed of, for example, an insulating material.

The conductive layer 122 may be formed on partial regions of the base substrate 110. The conductive layer 122 may be formed of a copper foil having a small thickness such that the pads 124 to be formed in a subsequent process may have electrically conductive properties.

The pads 124 may be formed on the conductive layer 122 and may be electrically connected to the semiconductor chip 200 via bumps 250. For example, the pads 124 may be formed as any one of a wire bonding pad, a flip chip pad, and a solder ball pad, on which the semiconductor chip 200 is mounted.

The gold plating layer 126 may be formed to contact upper surfaces of the pads 124 so as to prevent the surfaces of the pads 124 from being oxidized.

In addition, the gold plating layer 126 may increase the electric coupling of the surfaces of the pads 124, thereby increasing soldering properties during coupling with the semiconductor chip 200.

The gold plating layer 126 may be formed of, for example, an electrolytic gold plating material or an electroless gold plating material.

According to the present embodiment, an insulating layer 130 may be formed on the base substrate 110, except for regions on which the pads 124 are formed, and that is, may be formed on partial regions of the base substrate 110, on which the pads 124 are not formed, such that portions for forming the pads 124 may be defined.

Unlike the related art, in the package substrate 100 according to the present embodiment, the gold plating layer 126, which is formed via coating in order to increase electric coupling of the pads 124, may be formed on only the upper surfaces of the pads 124 rather than being formed on lateral surfaces of the pads 124, thereby miniaturizing intervals between adjacent pads to achieve high-density mounting.

In addition, unlike the related art, in the package substrate 100 according to the present embodiment, the pads 124 protrude from the base substrate 110, and thus, separate processes for embedding the pads 124 in the base substrate 110 are not required, thereby reducing manufacturing time and cost.

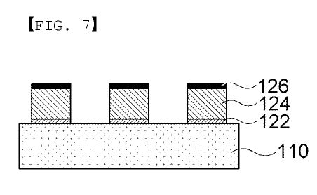

FIGS. 2 to 7 are cross-sectional views for describing a method of fabricating a package substrate, according to an embodiment of the present invention.

First, as shown in FIG. 2, the base substrate 110 is prepared.

According to the present embodiment, the base substrate 110 may function as a support for forming patterns including the conductive layer 122, the pads 124, and the gold plating layer 126 and may be formed of, for example, an insulating material.

Then, as shown in FIG. 3, a metal material layer 122a is formed to surround an entire surface of the base substrate 110.

The metal material layer 122a may be formed as the conductive layer 122 in a subsequent process.

The metal material layer 122a may be formed of a copper foil having a small thickness such that the pads 124 may have electrically conductive properties.

Then, as shown in FIG. 4, sacrificial patterns 150 are formed on partial regions of the base substrate 110 on which the metal material layer 122a is formed.

According to the present embodiment, the sacrificial patterns 150 may be formed to design shapes of patterns including the conductive layer 122, the pads 124, and the gold plating layer 126, which are to be formed in subsequent processes.

The sacrificial patterns 150 may be formed of, but are not limited to, various photosensitive materials such as photo resist or photo solder resist, or alternatively, may be formed of other various materials.

Then, as shown in FIG. 5, the pads 124 are formed between adjacent sacrificial patterns 150, and that is, are formed to contact lateral surfaces of the sacrificial patterns 150.

In this case, the pads 124 may each be formed to have a smaller height than that of each sacrificial pattern 150 so as to prevent the pads 124 from being removed together in a subsequent process for removing the sacrificial patterns 150.

Then, as shown in FIG. 6, the gold plating layer 126 is formed on upper surfaces of the pads 124.

In more detail, an electrolytic gold plating material or an electroless gold plating material may be deposited on the base substrate 110 on which the pads 124 are formed and then may be etched to form the gold plating layer 126 that remains on only the upper surfaces of the pads 124.

In this case, the gold plating layer 126 may each be formed to have a smaller height than that of each sacrificial pattern 150 so as to prevent the gold plating layer 126 from being removed together in a subsequent process for removing the sacrificial patterns 150.

Lastly, as shown in FIG. 7, the sacrificial patterns 150 may be entirely removed and the metal material layer 122a may be partially removed such that the conductive layer 122 may remain on only partial regions so as to contact lower surfaces of the pads 124.

Although not shown in FIGS. 2 to 7, the insulating layer 130 may be formed on the base substrate 110, except for regions on which the pads 124 are formed, and that is, may be formed on partial regions of the base substrate 110, on which the pads 124 are not formed, such that portions for forming the pads 124 may be defined.

Unlike the related art, in the method of fabricating the package substrate 100 according to the present embodiment, the gold plating layer 126, which is formed via coating in order to increase electric coupling of the pads 124, may be formed on only the upper surfaces of the pads 124 rather than being formed on lateral surfaces of the pads 124, thereby miniaturizing intervals between adjacent pads to achieve high-density mounting.

In addition, unlike the related art, in the method of fabricating the package substrate 100 according to the present embodiment, the pads 124 protrude from the base substrate 110, and thus, separate processes for embedding the pads 124 in the base substrate 110 are not required, thereby reducing manufacturing time and cost.

Although the preferred embodiments of the present invention have been disclosed for illustrative purposes, those skilled in the art will appreciate that various modifications, additions and substitutions are possible, without departing from the scope and spirit of the invention as disclosed in the accompanying claims. Accordingly, such modifications, additions, and substitutions should also be understood to fall within the scope of the present invention.

What is claimed is:

1. A method of fabricating a package substrate, comprising:
preparing a base substrate;
forming a metal material layer surrounding an entire surface of the base substrate;
forming sacrificial patterns on partial regions of the base substrate on which the metal material layer is formed;
forming pads contacting lateral surfaces of the sacrificial patterns;
forming a gold plating layer on upper surfaces of the pads; and
removing the sacrificial patterns and removing portions of the metal material layer to form a conductive layer that remains on partial regions so as to contact lower surfaces of the pads.

2. The method according to claim 1, wherein the pads are each formed to have a smaller height than that of each of the sacrificial patterns.

3. The method according to claim 1, wherein the gold plating layer is formed to have a smaller height than that of each of the sacrificial patterns.

4. The method according to claim 1, further comprising forming an insulating layer on the base substrate, except for the partial regions.

5. A package substrate comprising:
a base substrate;
a conductive layer formed on partial regions of the base substrate;
pads formed on the conductive layer; and
a gold plating layer that is formed to contact upper surfaces of the pads.

6. The package substrate according to claim 5, wherein the pads are electrically connected to a semiconductor chip via bumps.

7. The package substrate according to claim 5, further comprising an insulating layer formed on the base substrate, except for the partial regions.
